(19) United States
(12) Patent Application Publication
(10) Pub. No.: US 2026/0246233 A1
(43) Pub. Date: Aug. 20, 2026

(54) OPTOELECTRONIC SEMICONDUCTOR COMPONENT

(71) Applicant: ams-OSRAM International GmbH, Regensburg (DE)

(72) Inventors: Martin Rudolf BEHRINGER, Regensburg (DE); Lars NÄHLE, Bad Abbach (DE); Sönke TAUTZ, Tegernheim (DE)

(73) Assignee: ams-OSRAM International GmbH, Regensburg (DE)

(21) Appl. No.: 18/992,777

(22) PCT Filed: Jun. 30, 2023
(86) PCT No.: PCT/EP2023/068009

§ 371 Date: Jan. 9, 2025

(30) Foreign Application Priority Data
Jul. 13, 2022 (DE) 102022117503.0

(51) Int. Cl. H01S 5/06; H01S 5/026; H01S 5/028

(52) U.S. Cl. CPC H01S 5/0601; H01S 5/0265; H01S 5/0287

(57) ABSTRACT

The optoelectronic semiconductor component includes a semiconductor body having an active zone and segments, as well as a shielding structure. Two adjacent segments are separated by a trough that penetrates the active zone starting from a top side of the semiconductor body. The shielding structure is arranged on the top side and/or within the trough and is impermeable for radiation generated in the active zone.

### CROSS-REFERENCE TO RELATED APPLICATIONS

The present application is a national stage entry from International Application No. PCT/EP2023/068009, filed on Jun. 30, 2023, published as International Publication No. WO 2024/012895 A1 on Jan. 18, 2024, and claims priority to German Patent Application No. 10 2022 117 503.0, filed Jul. 13, 2022, the disclosures of all of which are hereby incorporated by reference in their entireties.

### FIELD

An optoelectronic semiconductor device is specified.

### BACKGROUND

One of the tasks to be solved is to specify an optoelectronic semiconductor device which has an improved beam quality.

This problem is solved by the device with the features of independent claim 1. Advantageous embodiments and further developments are the subject of the dependent claims.

### SUMMARY

According to at least one embodiment the optoelectronic semiconductor device comprises a semiconductor body with an active zone and segments. The active zone is arranged, for example, between a first semiconductor layer and a second semiconductor layer of the semiconductor body. For example, the first semiconductor layer has charge carriers of a first type, for example p-charge carriers or n-charge carriers. The second semiconductor layer has, for example, charge carriers of a second type, in particular of a type opposite to the first type.

For example, the first semiconductor layer is p-doped and the second semiconductor layer is n-doped. The first and second semiconductor layers can also each comprise two or more sub-layers and thus each be formed as semiconductor layer sequences.

For example, the semiconductor body is based on a nitride compound semiconductor material, such as AlₙIn₁₋ₙ₋ₘGaₘN, or on a phosphide compound semiconductor material, such as AlₙIn₁₋ₙ₋ₘGaₘP, or on an arsenide compound semiconductor material, such as AlₙIn₁₋ₙ₋ₘGaₘAs or AlₙIn₁₋ₙ₋ₘGaₘAsP, wherein in each case 0≤n≤1, 0≤m≤1 and m+n≤1. The semiconductor body may have dopants and additional components. For the sake of simplicity, however, only the essential components of the crystal lattice of the semiconductor body, i.e. Al, As, Ga, In, N and P, are specified, even if these may be partially replaced and/or supplemented by small amounts of other substances. Preferably, the semiconductor body is based on a III/V compound semiconductor material such as, for example, GaN.

For example, the semiconductor body is formed in one piece. In particular, the semiconductor body is produced in a common growth process. The semiconductor body is preferably divided into segments after the growth process has been completed.

The active zone is configured, for example, to generate electromagnetic radiation from a wavelength range between and the IR range and the UV range, inclusive. Preferably, radiation in the visible wavelength range is generated in the active zone during intended operation.

In particular, the active zone contains at least one quantum well structure, for example in the form of a quantum dot, a single quantum well, SQW for short, or in the form of a multi-quantum well structure, MQW for short, for generating radiation. In addition, the active zone contains one, preferably several, secondary well structures.

According to at least one embodiment, the optoelectronic device comprises a shading structure. The shading structure comprises, for example, one or more shading elements. Alternatively or additionally, the shading structure comprises one or more absorbing elements.

According to at least one embodiment, two adjacent segments are separated by a trench. Starting from an upper side of the semiconductor body, the trench completely penetrates the active zone. In particular, the trench provides electrical and/or optical separation of the segments. Preferably, the segments can be controlled and operated independently of each other. In particular, the segments form independent optoelectronic components with preferably different functions. The trench is introduced into the semiconductor body after the growth process, for example by means of an etching process. In particular, the segments are monolithically connected to each other.

The upper side of the semiconductor body is formed, for example, on the first semiconductor layer. In particular, the upper side is a surface of the first semiconductor layer that faces away from the active zone. Preferably, the trench penetrates the first semiconductor layer completely. For example, the trench protrudes into the second semiconductor layer.

It is possible that the trench is formed as a recess in the semiconductor body. In this case, the trench is completely surrounded by the semiconductor body when viewed in plan view of the upper side of the semiconductor body. In particular, in this case the first semiconductor layer and the active zone are formed contiguously.

Alternatively, it is possible for the trench to completely cut through the first semiconductor layer and possibly the active zone. For example, the trench runs across the entire width of the semiconductor body as seen in plan view. In this case, the first semiconductor layer and, if applicable, the active zone are not contiguous. In particular, this means that the active zone and the first semiconductor layer each comprise at least two sections that are not in direct contact with each other.

For example, at least one of the segments is configured to generate electromagnetic radiation, for example the first segment. The radiation is, for example, laser radiation. In particular, the first segment is configured to couple radiation into the trench.

A second segment is configured, for example, to couple this radiation from the trench. The first segment and the second segment are particularly adjacent. The second segment is, for example, a modulator that modulates the radiation of the first segment, for example by amplifying it. For example, a main emission surface of the optoelectronic component is arranged on a side opposite the trench in the region of the second segment. A main emission direction of the optoelectronic component is in particular perpendicular to the main emission surface.

There may also be further segments that follow the second segment. The segments are separated from each other and spaced apart by a trench. The segments can, for example, be arranged in succession parallel to a main emission direction of the semiconductor device, with a trench being arranged between every two adjacent segments.

According to at least one embodiment, the shading structure is arranged on the upper side and/or inside the trench. For example, the shading structure is configured to shade radiation that propagates inside the trench during intended operation and leaves the trench as scattered radiation, for example due to coupling losses. The shading is preferably carried out in such a way that parts of the scattered radiation that propagate in the direction of the main emission direction of the optoelectronic semiconductor device and/or at least partially in a direction towards the semiconductor body are suppressed.

According to at least one embodiment, the shading structure is impermeable and/or at least partially absorbent for radiation generated in the active zone, for example radiation that propagates inside the trench during intended operation. In particular, the shading structure is impermeable and/or at least partially absorbent for scattered radiation. Here and in the following, impermeable means in particular that a transmittance of the shading structure is less than 20% or less than 15% or less than 10% or preferably less than 5%.

Preferably, a material of the shading structure has a high degree of absorption, which is, for example, more than 50% or more than 60% or more than 70%.

In at least one embodiment, the optoelectronic device comprises a semiconductor body with an active zone and segments, and a shading structure. Two adjacent segments are separated by a trench that penetrates the active zone starting from an upper side of the semiconductor body. The shading structure is arranged on the upper side and/or inside the trench and is impermeable to the radiation generated in the active zone.

The optoelectronic semiconductor device described here is based on the following technical features, among others. A segmented semiconductor device allows several components with different functions to be generated monolithically on one chip. For example, a laser element can be combined with a detection element, such as a photodiode, or with an optical modulator, such as an amplifier or controllable absorber. To electrically and optically separate such segments, the active zone between the segments is removed by forming a trench. Independent electrical contacting of these segments is achieved, for example, via separate metallizations on the upper side of the semiconductor body.

Coupling radiation from one segment to the other via the trench always involves a loss due to the general divergence of the radiation. The loss is determined, for example, by the non-coupling of radiation from one segment into the other. This can result in losses due to radiation radiating out of the trench in the form of scattered radiation. It is also possible for radiation to be coupled into undesired regions of the semiconductor device, for example a substrate.

The aim is to make the coupling of radiation from one segment to the other as efficient as possible in order to increase the overall efficiency of the semiconductor device. However, complete overcoupling of the trench can typically not be achieved.

The semiconductor device described herein makes use, inter alia, of the idea of providing a shading structure. The shading structure is arranged in such a way that parts of undesired scattered radiation propagating in the direction of a main emission direction of the semiconductor device are suppressed. In this way, the scattered light can be kept away from an application downstream of the semiconductor device, thereby increasing the overall beam quality of the optoelectronic semiconductor device and achieving improved image quality.

If, for example, a laser element is used as the first segment and the second element forms an optical amplifier, the semiconductor device is particularly suitable as a light source in projection applications. Examples of such applications can be found in the field of augmented reality, also known as AR, and in the field of virtual reality, also known as VR. During operation, laser radiation is coupled from the first segment directly into the trench via a first flank of the trench. Coupling into the second segment takes place via an opposite second flank of the trench. The radiation is subsequently coupled out in a main emission direction towards the application via a facet of the semiconductor device in a region of the second segment.

Such projection applications often require a high dynamic range. This high dynamic range can preferably be achieved by amplification within the second segment. In this case, an at least partial occupation inversion is achieved about in the active zone in the region of the second segment without exceeding a laser threshold.

In order to achieve a particularly large dynamic range, radiation with a low intensity is preferably coupled into the second segment from the trench during operation. For example, the trench can be specifically designed in such a way that an increased radiation loss occurs inside the trench and only low-intensity radiation is coupled into the second segment.

At the same time, suppression of scattered radiation is particularly important in such applications, as this can overlap with the amplified radiation from the second segment and thus generate disturb signals in the application. A shading structure as described here is therefore particularly advantageous for such applications that require a high dynamic range.

According to at least one embodiment of the optoelectronic semiconductor device, the shading structure comprises a shading element that at least partially covers the second segment in plan view of the upper side. If the shading structure comprises several shading elements, the shading element of this embodiment is, for example, a first shading element. The shading element is structured as a layer on the upper side, for example. The shading element comprises, for example, a metal and/or a semiconductor material that reflects and/or absorbs scattered radiation. Alternatively or additionally, the shading element comprises a dielectric which is reflective and/or preferably absorbent for this radiation. For example, the shading element comprises one of the following materials or a combination of the following materials: gold, silver, aluminum, copper, platinum, silicon nitride, silicon, germanium, photoresists, mold materials, carbon-filled resists, organic coatings.

According to at least one embodiment of the optoelectronic component, the shading element at least partially covers the first segment, the second segment and the trench in plan view. For example, the trench is completely covered. The shading element is, for example, the first shading element as explained in connection with the embodiment described above. In this embodiment, the material of the shading element is preferably electrically insulating. By partially or completely covering the trench with a shading element, a particularly large proportion of the scattered radiation emerging from the trench can be advantageously shaded.

According to at least one embodiment, the shading structure comprises a shading element arranged directly on the upper side. If the shading structure already has a first shading element, the shading element of this embodiment is in particular a second shading element. The shading element is in direct contact with the upper side, for example. In particular, the shading element is in direct contact with the first semiconductor layer. The shading element may comprise the same structure and, in particular, the same materials as the shading element explained above.

According to at least one embodiment of the optoelectronic semiconductor device, the upper side, seen in plan view, is at most partially covered by the shading structure. Preferably, other sides of the semiconductor body, in particular side surfaces and/or facets, are also free of the shading structure. In other words, the shading structure does not form a housing or encapsulation or the like for the semiconductor body and/or the optoelectronic semiconductor device. In particular, the shading structure is also not part of a housing or encapsulation.

According to at least one embodiment of the optoelectronic semiconductor device, the shading structure comprises an absorbing element arranged inside the trench. If the shading structure comprises a plurality of absorbing elements, the absorbing element is in particular a first absorbing element. The absorbing element is arranged to absorb radiation propagating inside the trench. The absorbing element preferably has an absorption coefficient of at least 75% or at least 80% or at least 90% for this radiation. The absorbing element may be formed of a suitable material, which are mentioned above in connection with the shading element. Advantageously, such an absorbing element can be used to shade portions of the scattered radiation which, during operation, propagate in the direction towards the semiconductor body and/or, for example, in the direction towards a substrate of the semiconductor body.

According to at least one embodiment, the absorbing element at least partially covers a bottom region of the trench. In particular, the absorbing element completely covers the bottom region. Preferably, the trench extends into the second semiconductor layer. In particular, flanks of the trench are partially covered by the absorbing element. In particular, flanks of the trench connect the bottom region of the trench with the upper side. Starting from the bottom of the trench, for example, the absorbing element extends at most as far as the active zone.

According to at least one embodiment, the trench is at least partially filled with a filling material. In particular, the filling material is permeable to the radiation that propagates inside the trench during intended operation. This means in particular that a transmittance of the filling material is, for example, at least 70% or at least 80% or at least 90%. The filling material is silicon dioxide, for example.

Alternatively, it is possible for the transmittance to be at most 50% or at most 40% or at most 30%. Such a filling material can be used to reduce the intensity of radiation that is coupled into the second segment during operation. If the second segment acts as an amplifier, a particularly large dynamic range of the optoelectronic semiconductor device can be advantageously achieved.

Preferably, the trench is completely filled with the filling material. Filling the trench with the filling material facilitates the application of shading elements in particular. It is possible that shading elements, such as the first or second shading element, are arranged on the filling material, in particular arranged directly on it. It is also possible for a shading element to be arranged essentially exclusively on the filling material. In this case, the upper side can be free of the shading element in regions of the first and/or second segment. In a plan view of the upper side, only the trench is then partially or completely covered by this shading element.

According to at least one embodiment, a distance of the shading structure to an upper edge of the trench is at most 50 μm. For example, the distance is at most 30 μm or at most 10 μm. The distance may be an average distance between the upper edge and the shading structure in the lateral direction. The upper edge is defined, for example, by a line where flanks of the trench and the upper side meet. The upper edge can be recognized, for example, as the contour of the trench in plan view of the upper side. The lateral direction runs parallel to the main emission direction, for example. Preferably, the shading structure or at least one shading element is arranged directly at the upper edge. In particular, the distance between all shading elements and/or absorbing elements of the shading structure is at most 50 μm or at most 30 μm or at most 10 μm.

According to at least one embodiment of the optoelectronic semiconductor device, it comprises a first contact structure with a first metallization and a second metallization, as well as a second contact structure. The second contact structure is arranged, for example, directly on a side of the semiconductor body opposite the upper side. In particular, the second contact structure is in direct contact with the second semiconductor layer. For example, the second contact structure is configured for energizing and/or driving the second semiconductor layer.

For example, the first metallization is arranged directly on the upper side in the region of the first segment and the second metallization is arranged directly on the upper side in the region of the second segment. The first contact structure is configured for energizing and/or driving the first semiconductor layer. Preferably, the first metallization and the second metallization are electrically isolated from each other. In particular, by the first metallization and the second metallization the first segment and the second segment can be operated independently of each other. The first and second contact structures each comprise, for example, one or more of the following metals: gold, titanium, AuGe, Ni, ITO, palladium, aluminum, silver, copper, platinum.

According to at least one embodiment, the shading structure comprises a shading element arranged directly on the second metallization. If the shading structure already has one or more shading elements, the shading element of this embodiment is, for example, a second or a third shading element. The shading element has, for example, the same materials as the metallization. It is possible that the shading element and the second metallization are formed in one piece. Alternatively, the shading element has the same materials and/or composition as one of the above shading elements. It is possible that the shading element is also arranged on the first metallization, for example directly on the first metallization. In this case, the shading element is electrically insulating.

According to at least one embodiment, the second metallization has a cover region that partially covers the trench in plan view of the upper side. The cover region is part of the shading structure. In particular, the cover region is part of the second metallization and is preferably formed in one piece therewith. Preferably, in this embodiment, the trench is filled with the filling material. This makes it particularly easy to extend the second metallization in the cover region over the trench. For example, the cover region extends to the first metallization and/or the first segment in plan view without coming into mechanical and/or electrical contact with it.

According to at least one embodiment of the optoelectronic component, the optoelectronic component comprises a carrier with a first contact point and a second contact point. The first contact point is, for example, electrically conductively connected to the first metallization and the second contact point is electrically conductively connected to the second metallization, in particular directly connected. The carrier is, for example, a printed circuit board or a submount. The contact points are arranged, for example, on a main side of the carrier facing the semiconductor body. Advantageously, independent control of the first and second metallization and thus of the first and second segments is possible via the carrier. Furthermore, the carrier can advantageously increase the mechanical stability of the optoelectronic semiconductor device.

According to at least one embodiment, the shading structure comprises an absorbing element arranged between the first contact point and the second contact point of the carrier. If the shading structure already comprises an absorbing element, the absorbing element of this embodiment is in particular a second absorbing element. The absorbing element can advantageously be used to absorb scattered radiation that propagates from the trench in the direction towards the carrier. This prevents reflection of this scattered radiation from the carrier. The absorbing element can have the same physical properties and the same materials as the absorbing element described above.

According to at least one embodiment, the optoelectronic semiconductor device is an edge emitter. In particular, the semiconductor body comprises a waveguide on the upper side. The shading structure comprises at least one lateral shading element arranged next to the waveguide in plan view of the upper side. The waveguide defines, for example, a resonator axis for a laser resonator of the edge emitter.

In particular, the waveguide can be a ridge waveguide. These are also known as “ridges”, for example. The waveguide is part of the first semiconductor layer, for example. For example, in the case of a ridge waveguide, the waveguide protrudes from the first semiconductor layer.

It is possible that the trench extends through the active zone or to where the optical wave is guided. Furthermore, it is possible that the trench completely penetrates the waveguide. In particular, this means that the waveguide is completely removed in the region of the trench. In the case of the semiconductor device as an edge emitter, a main emission surface is formed in particular by a facet that runs perpendicular to the upper side. This facet is, for example, parallel to a main extension direction of the trench. In view of the main emission surface of the optoelectronic component, the upper side has a step in the case of a ridge waveguide.

In plan view of the upper side, the at least one lateral shading element is arranged in particular next to the trench. The lateral shading element may comprise one or more layers, which may be formed from one of the above-mentioned materials of the above shading elements. The lateral shading element is arranged in particular on, for example directly on, the upper side. Alternatively or additionally, the lateral shading element comprises at least one recess which is filled, for example, with an absorbent material. The absorbent material may be a material of the absorbing element.

According to at least one embodiment of the optoelectronic semiconductor device, the first segment is a laser element and the second segment is an optical modulator or a detection element. The first segment preferably comprises at least one laser resonator, in which laser radiation is generated during intended operation. Preferably, this laser radiation is coupled from the first segment into the trench during operation. At least part of this radiation is coupled into the second segment, where it is optically modulated, for example.

According to at least one embodiment, the optoelectronic component comprises a first facet and a second facet. The first facet has a reflectance of at least 50%, in particular at least 80%, preferably at least 95%. A first section of the active zone is bounded by the first facet and a first flank of the trench in the main emission direction. In particular, the first section is assigned to the first segment. The second facet has a reflectance of at most 50%, in particular at most 20%, preferably at most 5%. A second section of the active zone, which is assigned in particular to the second segment, is bounded in emission direction by the second facet and a second flank of the trench. The reflectance indicates in particular the proportion of an incident intensity that is reflected at the corresponding facet or flank.

A reflectance of the reflective structure formed with at least one trench is in each case between 10% and 90% inclusive, in particular 99% inclusive.

The first section preferably forms a laser oscillator. In particular, laser radiation is coupled into the trench at the first flank of the trench during intended operation. For example, at least part of this laser radiation is coupled into the second section at the second flank of the trench during intended operation. In particular, the first flank is opposite the second flank. At a main emission surface of the semiconductor body opposite the trench in the region of the second segment, the radiation is coupled out of the semiconductor device during intended operation. In particular, the second section forms an amplifier for the laser radiation. In particular, no laser resonator is formed in the second section due to the selected degree of reflection of the second facet. Due to the amplification, it is possible to realize a semiconductor device with a high dynamic range.

Further advantages and advantageous embodiments and further developments of the optoelectronic semiconductor device can be seen from the exemplary embodiments shown below in connection with schematic drawings. Identical, similar and identically acting elements are provided with the same reference signs in the figures. The figures and the proportions of the elements shown in the figures should not be considered to be to scale. Rather, individual elements may be shown in exaggerated size for better visualization and/or understanding.

### BRIEF DESCRIPTION OF THE DRAWINGS

In the figures:

FIG. 1 shows a schematic sectional view of a modification of an optoelectronic semiconductor device;

FIGS. 2 to 9 show schematic sectional views of various exemplary embodiments of an optoelectronic semiconductor device described herein; and

FIG. 10 shows a schematic plan view of an exemplary embodiment of an optoelectronic semiconductor device described herein.

### DETAILED DESCRIPTION

The modification 100 of the optoelectronic semiconductor device according to FIG. 1 has a semiconductor body 2. The semiconductor body 2 comprises a first semiconductor layer 21, a second semiconductor layer 22 and an active zone 23 arranged between the first and second semiconductor layers 21, 22. The first semiconductor layer 21 is, for example, p-doped and the second semiconductor layer 22 is, for example, n-doped or vice versa. The semiconductor body 2 is formed with a III/V compound semiconductor material, in particular with GaN. The semiconductor body 2 is formed in one piece, for example, and is produced in a single growth process.

A trench 6 completely penetrates the first semiconductor layer 21 and the active zone 23 starting from an upper side 26 of the semiconductor body 2. The semiconductor body 2 is divided by the trench 6 into a first segment 3 and a second segment 4. The segments 3, 4 are electrically and/or optically separated from each other.

The modification 100 further comprises a second contact structure 30 and a first contact structure 31, 32. The second contact structure 30 is arranged to supply the second semiconductor layer 22 with current during intended operation. For this purpose, the second contact structure 30 is arranged on a side of the semiconductor body 2 opposite the upper side 26 and is in direct contact with the second semiconductor layer 22.

The first contact structure 31, 32 is configured to supply the first semiconductor layer 21 with current during intended operation. The first contact structure 31, 32 comprises a first metallization 31 and a second metallization 32. The first metallization 31 is arranged in direct contact with the upper side 26 in the region of the first segment 3. The second metallization 32 is arranged in direct contact with the upper side in the region of the second segment 4. The segments 3, 4 can be operated independently of one another via the first metallization 31 and the second metallization 32. The second contact structure 30 and the first contact structure 31, 32 each comprise one or more metals, such as gold, titanium, AuGe, Ni, ITO, palladium, aluminum, silver, copper, platinum.

The active zone 23 comprises a first section 24 and a second section 25. The first section 24 is assigned to the first segment 3 and the second section 25 is assigned to the second segment 4. The first section 24 is bounded in direction of a main emission direction 9 by a first facet 28 and a first flank 61 of the trench 6. The active zone 23 is in the first section 24 configured to generate a laser radiation in the visible spectral range. For this purpose, a laser resonator is formed in the first section 24.

The first facet 28 has a high degree of reflection, for example over 90%, preferably over 95%. The first flank 61 has a reflectance between 10% and 90% inclusive, for example 50%. The first flank 61 serves as a decoupling surface for laser radiation generated in the first section 24. During intended operation, this radiation 7 propagates in the trench 6.

The second segment 4 forms an optical amplifier for radiation which, in operation, is coupled into the second section 25 via a second flank 62. The second flank 62 is opposite the first flank 61 of the trench 6. The second section 25 is bounded by the second flank 62 of the trench 6 and a second facet 29 in the emission direction 9. A reflectance of the second flank 62 is, for example, between 10% and 90% inclusive and a reflectance of the second facet 29 is, for example, at most 5% or at most 10%. In particular, no laser resonator is formed in the second segment 4. In particular, during operation, an at least partial occupation inversion is brought about in the second section 25 without a laser threshold being exceeded.

The second facet 29 forms a main emission surface of the modification 100. The modification 100 is an edge emitter whose main emission direction 9 is perpendicular to the second facet 29. By forming the second segment 4 as an amplifier, the dynamic range of the modification 100 can be increased.

During operation, radiation 7 spreads inside the trench 6. This radiation 7 is not completely coupled into the second segment 4, but can leave the trench 6 as scattered radiation 71. For example, some of the scattered radiation exits in a direction towards the upper side 26 and in a direction parallel to the main emission direction 9 as illustrated by the arrows in FIG. 1. It is also possible that the scattered radiation 71 additionally enters the semiconductor body 2.

Radiation emitted by the semiconductor device in the main emission direction 9 can overlap with the scattered radiation 71 during operation. This reduces the beam quality and the image quality of the modification 100. Unwanted disturbance signals caused by the scattered radiation 71 are particularly problematic in applications that require a high dynamic range.

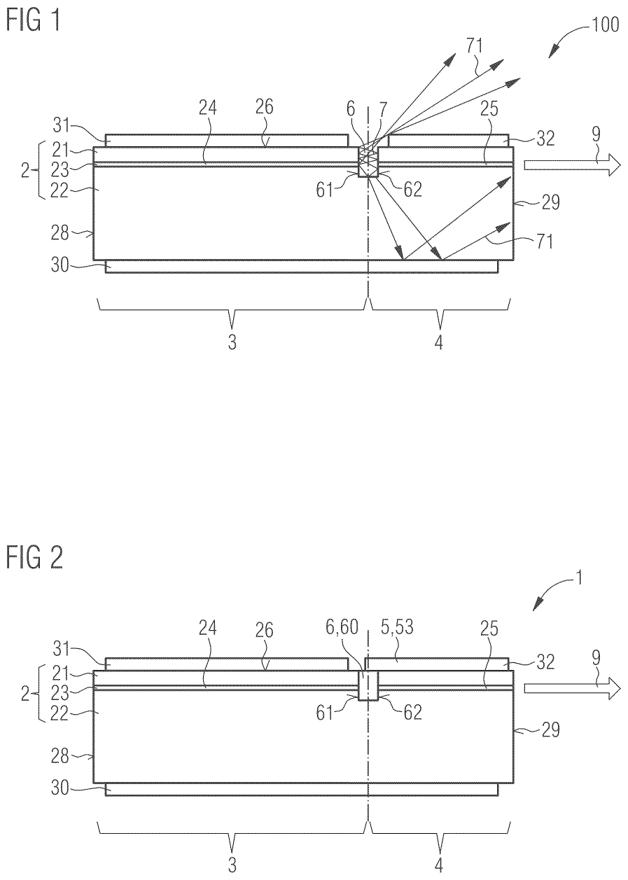

FIG. 2 shows an exemplary embodiment of an optoelectronic semiconductor device 1 described herein, in which these disadvantages are at least partially overcome. In contrast to the modification 100 of FIG. 1, the optoelectronic semiconductor device 1 comprises a filling material 60 with which the trench 6 is completely filled. Furthermore, the metallization 32 has a larger extent, so that it extends over the trench 6 in a cover region 53. In plan view of the upper side 26, the trench 6 is thus at least partially covered by the cover region 53.

The filling material 60 is preferably transparent for the radiation 7 that propagates inside the trench during operation. The filling material 60 is formed with or from silicon dioxide, for example. Due to the filling material 60, the second metallization 32 can extent over the trench 6 particularly easily. The cover region 53 shades or at least partially absorbs scattered radiation 71 that propagates in the direction of the upper side 26 and the main emission direction 9. The cover region 53 is thus part of a shading structure 5. Advantageously, a portion of the scattered radiation 71 can thus be suppressed. In particular, those portions of the scattered radiation 71 that would propagate in the direction of the main emission direction 9 are suppressed.

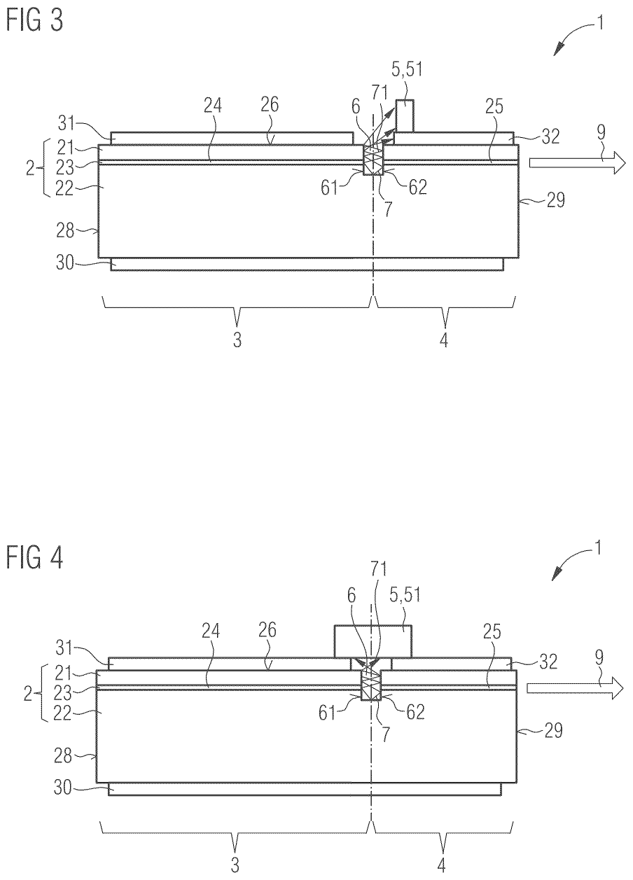

FIG. 3 shows an optoelectronic semiconductor device 1 according to a second exemplary embodiment. The semiconductor device 1 comprises essentially the same features as the semiconductor device of FIG. 2, with the difference that the shading structure 5 is not formed with an cover region 53 of the second metallization 32, but comprises a shading element 51. Furthermore, the trench 6 is free of filling material. The shading element 51 is arranged on the upper side 26. The shading element 51 is arranged in direct contact with the second metallization 32. The shading element 51 forms a shading structure 5 for scattered radiation 71. The shading element 51 is configured to be impermeable to radiation 7 that propagates inside the trench 6 during operation, and in particular to scattered radiation 71. This means that a transmittance of the shading element 51 is, for example, at most 10% for this radiation 7.

The shading element 51 is, for example, structured as a layer, formed with a dielectric and has a degree of absorption for the scattered radiation 71 of, for example, more than 70%. The shading element 51 is formed, for example, with silicon nitride, an inorganic coating or a photoresist. In plan view of the upper side 26, the shading element 51 partially covers the second segment 4.

Parts of the scattered radiation 71 that propagate in the direction of the main emission direction 9 can be suppressed with this shading element 51 as illustrated in conjunction with the arrows 71 in FIG. 3. In this way, disturbance signals in the application due to the scattered radiation 71 can be reduced and the beam quality of the optoelectronic semiconductor device 1 can be increased.

The exemplary embodiment of the optoelectronic semiconductor device 1 according to FIG. 4 differs from the exemplary embodiment of FIG. 3 in that the shading element 51 partially covers the first segment 3, the second segment 4 and the trench 6 in plan view of the upper side 26. It is also possible that the shading element 51 completely covers the trench 6. In the present case, the shading element 51 is arranged in direct contact with the first metallization 31 and the second metallization 32. Preferably, the shading element 51 is electrically insulating. With a shading element 51 arranged in this way, scattered radiation 71 can be effectively shielded. Thus, not only parts of the scattered radiation 71 that propagate in direction of the main emission direction 9, but also parts of the scattered radiation 71 that leave the trench 6 in ther directions can be suppressed, as illustrated by the arrows in FIG. 4.

The exemplary embodiment of FIG. 5 differs from the exemplary embodiment of FIG. 3 in that the trench 6 is filled with the filling material 60. Furthermore, the shading element 51 is arranged directly on the upper side 26. Thus, the shading element 51 is in direct contact with the first semiconductor layer 21. The shading element 51 is arranged directly on an upper edge of the trench 6. The upper edge of the trench is defined by a line at which the upper side 26 meets the flanks 61, 62 of the trench 6. A particularly close arrangement of the shading element 51 or the shading structure 5 to the upper edge of the trench 6 allows the scattered radiation 71 to be shaded particularly effectively.

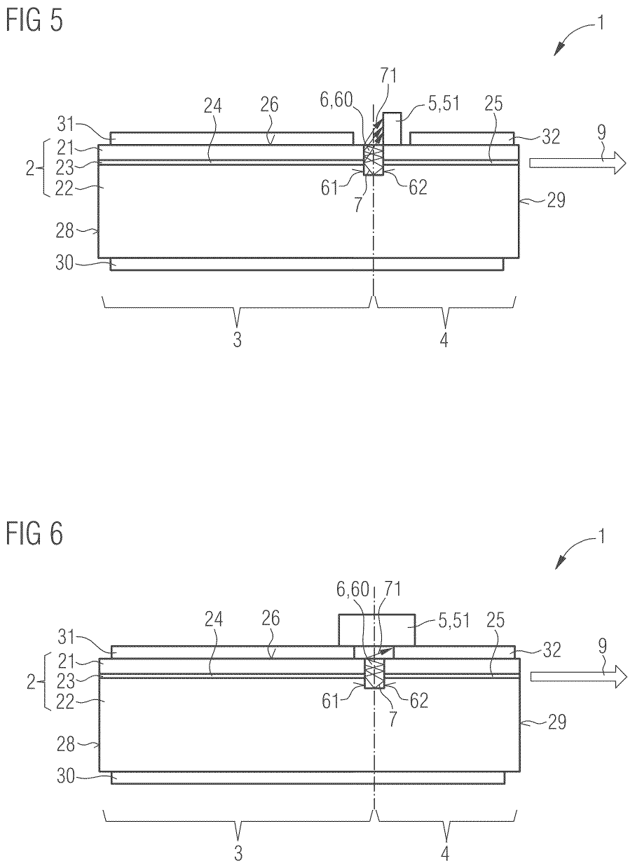

The exemplary embodiment of the optoelectronic semiconductor device 1 of FIG. 6 differs from the exemplary embodiment of FIG. 4 only in that the trench 6 is filled with the filling material 60.

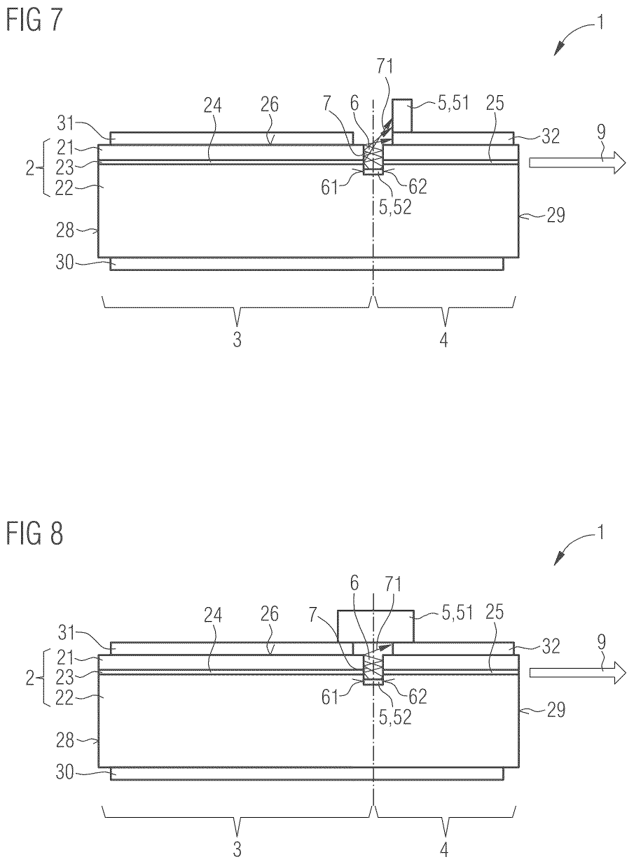

In the exemplary embodiment of the optoelectronic semiconductor device 1 according to FIG. 7, an absorbing element 52 is additionally arranged inside the trench 6, in contrast to the exemplary embodiment of FIG. 3. The absorbing element 52 and the shading element 51 together form the shading structure 5. In contrast to FIG. 5, it is also possible for the shading structure 5 to have only an absorbing element 52. It is also possible that the shading structures 5 of all other embodiments also have an absorbing element 52.

The absorbing element 52 is preferably formed with a dielectric and has an absorption coefficient of at least 80% or at least 90% for the scattered radiation 71. The absorbing element 52 completely covers a bottom region of the trench 6 and partially covers flanks 61, 62 of the trench 6. Measured from the bottom of the trench 6, the absorbing element 52 preferably does not reach the active zone 23. The absorbing element 52 allows scattered radiation 71, which would propagate in a direction towards the semiconductor body 2, to be shielded. Thus, a particularly large proportion of scattered radiation 71 can be suppressed with a shading structure 5. The scattered radiation 71 also comprises, for example, unwanted and/or unused laser radiation which, although it couples into the following segment, couples too deeply and would therefore not reach the active zone but non-guiding layers.

The exemplary embodiment of FIG. 8 differs from the exemplary embodiment of FIG. 7 only in that the shading element 51 at least partially covers the first segment 3, the second segment 4 in each case and the trench 6 in plan view of the upper side 26, as explained, for example, in connection with FIG. 4.

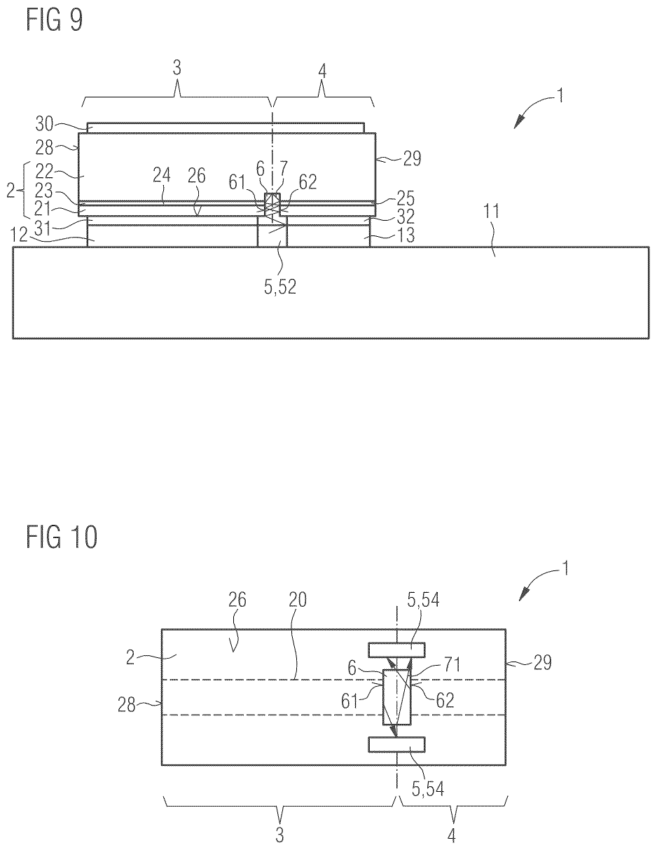

FIG. 9 shows a further exemplary embodiment of an optoelectronic semiconductor device 1 described herein. The semiconductor device 1 of FIG. 9 comprises in particular all the features of the semiconductor device of FIG. 3, with the difference that no shading element 51 is present. Furthermore, the semiconductor body 2 is mounted on a carrier 11. The carrier 11 has a first contact point 12 and a second contact point 13 on a main side facing the semiconductor body 2. The first contact point 12 and the first metallization 31 are electrically conductively connected to each other. The second contact point 13 and the second metallization 32 are electrically conductively connected to each other. The carrier 11 is, for example, a printed circuit board with which the segments 3, 4 of the semiconductor body 2 can be controlled independently of one another via the contact points 12, 13.

A shading structure 5 is arranged on the upper side 26 between the first contact point 12 and the second contact point 13. The shading structure 5 comprises an absorbing element 52. The absorbing element 52 scattered radiation 71 that would emerge from the trench 6 in the direction of the carrier 11 during intended operation can be absorbed and suppressed. Reflections of the scattered radiation 71 at the carrier 11 can thus be reduced, whereby the beam quality of the optoelectronic semiconductor device 1 can be increased.

FIG. 10 shows a plan view of an upper side 26 of an optoelectronic semiconductor device 1 according to a further exemplary embodiment. The optoelectronic device 1 has a waveguide 20. The waveguide 20 extends from a first facet 28 to a second facet 29, which forms a main emission surface of the optoelectronic semiconductor device 1. The first facet 28 and the second facet 29 each extend perpendicular to the upper side 26.

The waveguide 20 is interrupted by a trench 6. That is, the waveguide 20 is completely severed in the region of the trench 6. In particular, a first section of the waveguide 20 runs from the first facet 28 to a first flank 61 of the trench 6 and a second section runs from a second flank 62 of the trench 6 to the second facet 29. The first section is assigned to a first segment 3 and the second section is assigned to a second segment 4 of the semiconductor body 2. The waveguide 20 defines a resonator axis for a laser resonator at least in the region of the first segment 3.

Lateral shading elements 54 are arranged to the side of the waveguide 20 and besides the trench 6. The two lateral shading elements 54 form a shading structure 5. The lateral shading elements 54 are, for example, each formed as recesses into which an absorbent material is inserted. For example, the absorbent material is the same material with which the absorbing element 52 is formed.

Alternatively, at least one of the lateral shading elements is formed in the form of an additional layer. For example, the additional layer is formed like a shading element 51 according to one of the other exemplary embodiments, in particular with the same material.

It is possible that a waveguide as shown in FIG. 10 is also present in all other embodiments. For example, sectional planes of the sectional views of FIGS. 2 to 9 can run perpendicular to the upper side 26 through a waveguide.

Lateral shading elements 54 may also be provided in any of the other exemplary embodiments. Likewise, the shading structure 5 of FIG. 10 may comprise further shading elements 51 and/or absorbing elements 52 according to one of the other exemplary embodiment. Such lateral shading elements 54 can be used to shade parts of the scattered radiation 71 that leave the trench 6 in lateral directions, as illustrated by the arrows 71 in FIG. 10.

The invention is not limited to the description based on the exemplary embodiments. Rather, the invention includes any new feature as well as in the combination of features, which includes in particular any combination of features in the patent claims, even if this feature or combination itself is not explicitly stated in the patent claims or embodiments.

1. An optoelectronic semiconductor device comprising:
a semiconductor body with an active zone and segments, and
a shading structure, wherein
two adjacent segments are separated by a trench which, starting from an upper side of the semiconductor body, penetrates the active zone completely,
the shading structure comprises a shading element on the upper side and/or an absorbing element inside the trench, and
the shading structure is impermeable and/or absorbent for radiation generated in the active zone, and
the absorbing element, starting from a bottom region of the trench, extends at most as far as the active zone.

2. The optoelectronic semiconductor device according to claim 1, wherein the shading element at least partially covering at least a second segment in plan view of the upper side.

3. The optoelectronic semiconductor device according to claim 1 wherein, in plan view of the upper side the shading element at least partially covers a first segment the second segment and the trench in each case.

4. The optoelectronic semiconductor device according to claim 1, wherein the shading element being arranged directly on the upper side.

5. The optoelectronic semiconductor device according to claim 1, wherein the upper side, seen in plan view, is at most partially covered by the shading structure.

6. The optoelectronic semiconductor device according to claim 1, wherein the absorbing element at least partially covers a bottom region of the trench.

7. The optoelectronic semiconductor device according to claim 1, wherein the trench is at least partially filled with a filling material.

8. The optoelectronic semiconductor device according to claim 1, wherein a distance of the shading structure to an upper edge of the trench is at most 50 μm.

9. The optoelectronic semiconductor device according to claim 1, the shading element being arranged directly at an upper edge of the trench.

10. The optoelectronic semiconductor device according to claim 1, further comprising a
first contact structure with a first metallization and a second metallization and
a second contact structure, wherein
the second contact structure is arranged directly on a side of the semiconductor body opposite the upper side,
the first metallization is arranged directly on the upper side in the region of a first segment, and
the second metallization is arranged directly on the upper side in the region of a second segment.

11. The optoelectronic semiconductor device according to claim 10, wherein the shading structure comprises a shading element arranged directly on the second metallization.

12. The optoelectronic semiconductor device according to claim 10, in which the second metallization at least partially covers the trench in a cover region in plan view of the upper side, wherein the cover region is part of the shading structure.

13. The optoelectronic semiconductor device according to claim 10, further comprising a carrier having a first contact point and a second contact point, wherein the first contact point is electrically conductively connected to the first metallization and the second contact point is electrically conductively connected to the second metallization.

14. The optoelectronic semiconductor device according to claim 13, wherein the shading structure comprises an absorbing element arranged between the first contact point and the second contact point.

15. The optoelectronic semiconductor device according to claim 1, wherein the semiconductor device is an edge emitter in which
the semiconductor body comprises a waveguide on the upper side, and
the shading structure comprises at least one lateral shading element which is arranged next to the waveguide in plan view of the upper side.

16. The optoelectronic semiconductor device according to claim 1, wherein
a first segment forms a laser element, and
a second segment forms an optical modulator or a detection element.

17. The optoelectronic semiconductor device according to claim 1, further comprising a first facet and a second facet, wherein
the first facet has a reflectance of at least 80%,
a first section of the active zone is bounded by the first facet and a first flank of the trench in a main emission direction,
the second facet has a reflectance of at most 20%,
a second section of the active zone is bounded by the second facet and a second flank of the trench in the main emission direction, and
a reflectance of the flanks of the trench is in each case between 10% and 90%, inclusive.
